(19) United States
(12) Patent Application Publication
(10) Pub. No.: US 2006/0186312 A1
(43) Pub. Date: Aug. 24, 2006

(54) Apparatus and method for optical wavefront analysis using active light modulation

(76) Inventors: Zino Altman, Newtown, PA (US); Richard S. Koplin, New York, NY (US)

Correspondence Address: BAKER & BOTTS, 30 ROCKEFELLER PLAZA, 44TH FLOOR, NEW YORK, NY, 10112, US

(21) Appl. No.: 11/065,639

(22) Filed: Feb. 23, 2005

(51) Int. Cl. G01J 1/20; H01L 27/00

(52) U.S. Cl. 250/201.9; 250/208.1

(57) ABSTRACT

Apparatus and method for measuring wavefront slope and irradiance of direct and/or reflected light beams at a plurality of points to enable calculation of optical wave front distortions. A plurality of sub-beams or groups of sub-beams is created and controlled using at least one electronically-controlled Active Light Modulation Device (“ALMD”).

### FIELD OF THE INVENTION

The present invention relates to wavefront distortion analysis and constitutes an improvement of known Schack-Hartmann analyzer/sensors that are used to analyze wavefront distortion/variation.

### BACKGROUND OF THE INVENTION

The Shack-Hartmann sensor (or “SHS”) was first developed by Ben Platt and Roland Shack in 1970 as part of a classified U.S. Air Force laser project and has since seen widespread use in the measurement of wavefront aberrations in a variety of optical systems in fields ranging from astronomy to opthalmics. The SHS analyzes a wavefront transmitted by, or scattered from, an object of interest by dissecting the wavefront into a large number of subfronts using an array of microscopic lenses. The object of interest is frequently a component or components of an optical system having selected and pre-defined optical properties.

In the conventional SHS the array comprises micro-lenses or lenslets disposed in the same plane, such that their center points define a square lattice, with each micro-lens acting as a small aperture. A perfect plane wave incident along the optic axis of such an array will generate a square array of points of equal intensity in the back-focal-plane, each point originating from one of the micro-lenses. Any variance in the wavefront will cause a deflection of one or more points of the square lattice, giving rise to a streak of intensity in the back focal plane originating at the discrete point produced by a plane wave. It is well known in the art that, from measurements the displacement of the points of the square lattice, the wavefront slope across each sub-aperture can be determined and thus the optical properties of the object or system of interest derived. A wavefront sensor using a lenslet array is described in U.S. Pat. No. 6,396,588 to Sei. Various types of apparatus for the measurement and mapping of optical components using lenslet arrays are described in U.S. Pat. Nos. 4,725,138 to Wirth et al., U.S. Pat. No. 5,083,015 to Witthoft et al., and U.S. Pat. No. 5,825,476 to Abitol et al.

An SHS utilizing an array of equal-sized microscopic lenses pre-fabricated from a transparent material as a single component will have fixed optical properties—e.g., back focal plane, numerical aperture—which places limits on existing technology.

First, if the variance in wavefront slope across a lenslet in a fixed array increases above a certain value, individual wavefronts from different micro-lenses will overlap in the back focal plane, leading to a loss of all useful information. For a fixed lenslet array this problem cannot be overcome by expanding the wavefront, since the sampling density will be correspondingly decreased. Simply put, sensitivity (the smallest wavefront variation that can be detected) and dynamic range (the range of wavefront variation that can be detected) cannot be decoupled for a fixed lenslet array. The potential for overlap is one of the most commonly known shortfalls of SHS technology.

Second, in a conventional SHS, the size of the micro-lenses—around 144 μm in diameter, on average—places an upper limit on the spatial sampling frequency of the SHS. Even the best commercially available SHS systems manufactured by Zeiss and WaveFront Sciences have a spatial resolution of only 210 μm. With a resolution of 210 μm, direct data acquisition from a 10 mm diameter area will produce a total of only 3680 data points, allowing for about 60% area coverage due to effects of the lens size and spacing. (The limited fill factor and optical losses of a conventional fixed lenslet array imposing a further limit on the accuracy of the wavefront sensing.)

Third, the micro lenses that are used in conventional SHSs have fixed focal distances and spacings that allow for a only a limited dynamic range. As discussed above, any attempt to increase the dynamic range of a fixed lenslet array will inevitably be offset by a loss in its sensitivity.

### SUMMARY OF THE INVENTION

The present invention replaces the fixed lenslet array of a conventional SHS with one or more computer-controlled reflective or refractive active light modulation devices (“ALMDs”) that dissect the wavefront formed by passage through or scattering from an object of interest. By so doing, dynamic range and sensitivity may be dramatically increased over conventional devices and methods, thereby allowing faster and more precise wavefront profiling/analysis.

### BRIEF DESCRIPTION OF THE DRAWINGS

FIG. 1 shows a conventional SHS using a fixed lenslet array.

FIG. 2 shows a modified wavefront sensor using an ALMD instead of a lenslet array.

FIG. 3 shows an ALMD used to expand a wavefront.

FIG. 4 shows an ALMD used to contract a wavefront.

FIG. 5 shows multiple ALMDs being used to analyze a large area wavefront.

FIG. 6 shows two ALMDs used to further dissect and direct subfronts from a large wavefront.

FIG. 7 shows further processing of the elementary wavefront using smaller mirrors.

FIG. 8 shows a pattern for a progressive power contact lens with three zones.

FIG. 9 shows active wavefront corrections using two or more ALMDs.

FIG. 10 shows the implementation of closed feedback control of an ALMD wavefront sensor.

FIG. 11 shows a schematic from which the theoretical sensitivity and dynamic range of an ALMD wavefront sensor may be calculated.

FIG. 12 show a method for performing three-dimensional surface reconstruction.

### DETAILED DESCRIPTION

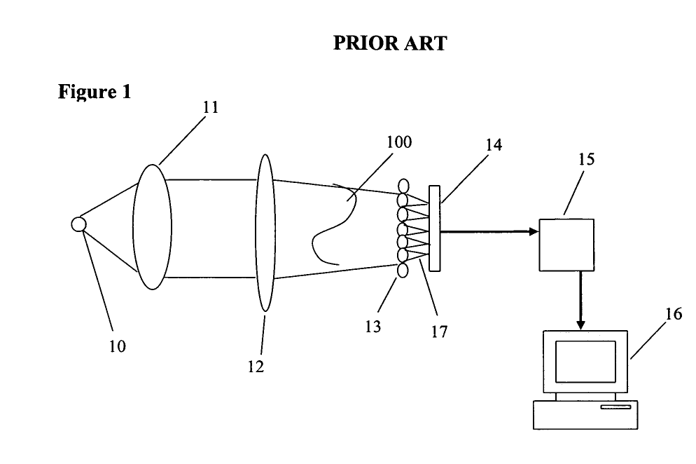

FIG. 1 is a schematic of a conventional SHS. A wavefront 100 created by light source 10 and a condenser lens or lens system 11 is distorted by an optical or other element 12 and dissected by a lenslet array 13 into plurality of sub fronts 17 that are focused onto a photo sensor 14. The signal from photo sensor 14 is processed by the processor 15 and sent to personal computer 16 for final data analysis and wavefront reconstruction.

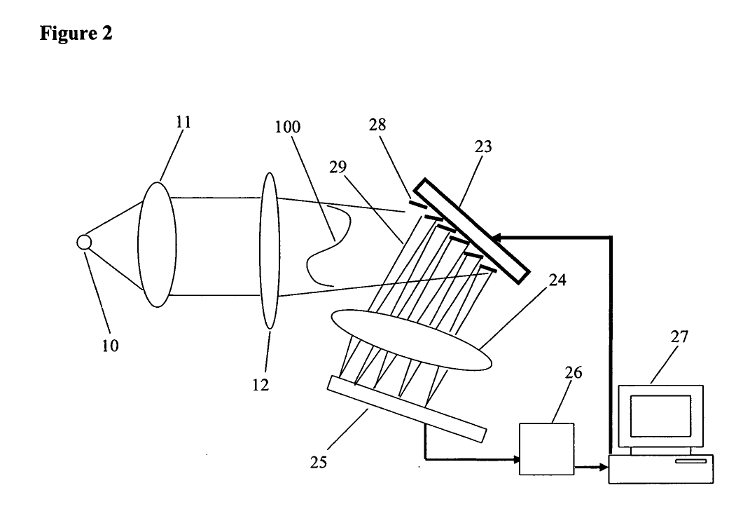

An embodiment of the invention is shown in the schematic of FIG. 2. A single ALMD 23 having reflective elements 28 is used in place of the conventional lenslet array of FIG. 1. (Such reflective ALMDs are commercially available from Texas Instruments (DMD), Silicon Light Machines, Corning, Agere Systems, Hitachi, Mitsubishi, Daewoo.) A wavefront or wavefront portion 100 created by light source 10 and a condenser lens or lens system 11 is distorted by an optical or other element 12 and then reflected by individual reflective elements 28 of an ALMD 23 creating a plurality of individual wave fronts 29. The operation of ALMDs is described in U.S. Pat. No. 4,680,579 to Ott et al., and U.S. Pat. No. 4,954,789 to Sampsell. Subfronts 29 then pass through an optional imaging lens 24 and are projected onto a photosensitive device 25, which generates a signal that is transmitted to personal computer 27 via a signal processor 26. Photo sensor 25 may be a charge coupled device (“CCD”), a complimentary metal oxide silicon (“CMOS”) device, a position sensitive diode array (“PSD”), a p-type-doping, insulator, n-type doping (“PIN”), or other suitable detector. (Light sensitive devices such of the CCD, CMOS, PSD, PIN, etc., types are available from a variety of manufacturers, including Sony, Kodak, Panasonic, Pulnix, Dalsa, and others.). Processor 26 may be a commercially available image processing board. The central processing unit of personal computer 27 may be programmed to determine the intensity/optical flux of each subfront 29 from the processed detector ouput and to apply wavefront reconstruction methods that are well known in the art to reconstruct the wavefront.

The reflective elements 28 of ALMD 23 may be steerable planar mirrors. By way of example, a typical ALMD device currently offered by Texas Instruments (see, e.g., Product Preview Data Sheet TI DN 2505686 REV C, DMD 0.7 XGA 12° DDR DMD Discovery, August 2004) has aluminium mirrors offset by 45° from the ALMD surface plane and tiltable between extrema at ±15° at a frequency of 40 kHz. In such a computer-controllable ALMD, the planar reflective elements 28 may be switched between a series of predetermined or programmed positions to define wavefront dissection patterns, which may dissect, expand and/or contract the wavefront portion that is incident on the ALMD. The switching movement of reflective elements 28 may be angular or linear. On the other hand, rather than being planar, reflective elements 28 may be parabolic or other shaped. Furthermore, reflective ALMD 23 be substituted by an ALMD having switchable refractive elements, such as prisms, or switchable transmissive elements, such as translucent windows or apertures having micro-mechanical shutters or translucent windows whose optical transmissivity may be switched electronically. Various light modulating devices are described in U.S. Pat. No. 5,311,360 to Bloom et al., U.S. Pat. No. 4,954,789 to Sampsell and U.S. Pat. No. 4,680,579 to Ott.

The central processing unit of personal computer 27 may be programmed to derive the wavefront distortion from the output of photodetector/photosensor 25 using standard wavefront reconstruction techniques (see, e.g., U.S. Pat. No. 5,479,257 to Hashimoto) and control the dissection of wavefront 100 using a commercial graphics package to generate wavefront dissection patterns and a standard driver to control ALMD 23 (available from the manufacturer).

In view of the rapid response time of ALMDs and the capacity to independently and controllably switch their reflective or other optical elements (currently available ALMDs manufactured by Texas Instruments may be switched at a rate of 40 kHz), such closed loop feedback allows real-time changes to be made in the size and placement of subfronts 29 on photodetector 25 by changing which reflective elements 28 contribute to each subfront 29. Accordingly, overlap of subfronts 29 on photodetector 25 may be eliminated and an optimum number and distribution of subfronts, and thus data points, generated for any given wavefront or wavefront portion. Datapoints corresponding to a all or some of subfronts 29 may be acquired sequentially. Such sequential data acquisition may be used to minimize statistical sampling errors in wavefront portions having greater wavefront variance. Furthermore, different dissection patterns may be used to reconstruct the same wavefront or wavefront portion and the accuracy of the reconstruction checked by comparing the reconstructions obtained using the different dissection patterns.

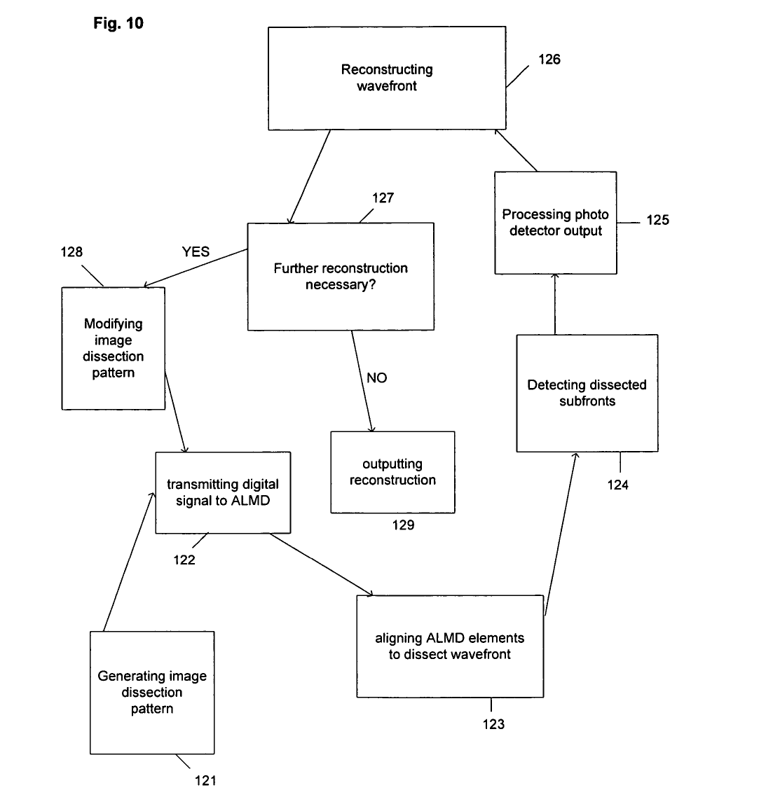

Furthermore, since the wavefront analysis and dissection may be performed in real time, a closed feedback loop may be implemented, as shown in FIG. 10. With reference to the components shown schematically in FIG. 2, the method of FIG. 10 may comprise steps 121-129. Step 121 involves generating an image dissection pattern (the initial pattern may be generated using any commercial graphics package running on personal computer 27). Step 122 involves transmitting a signal to ALMD 23 (this may be done using an analog or digital ALMD driver running on personal computer 27). Step 123 involves aligning reflective elements 28 to dissect wavefront 100 into subfronts 29. Step 124 involves collecting data from subfronts 29 using photodetector 25. Step 125 involves processing the output of photodetector 25 using processor 26 (this may be done using an image processor board to produce an image frame). Step 126 involves reconstructing the wavefront or wavefront portion 100 (this may be done by analyzing the image frame using the programmed central processing unit of personal computer 27). Step 127 involves determining whether more information about the reconstructed wavefront or wavefront portion is required (this may involve using the programmed central processing unit of personal computer 27 to compare wavefront reconstructions obtained using different dissection patterns, e.g., with square of circular symmetry, to determine whether the reconstructed wavefront is properly independent of the pattern, as discussed above, or consist of comparing the spatial data point density/sensitivity/dynamic range or other metric to some pre-determined threshold value or values). If more data is required, according to step 128, the image dissection pattern is modified accordingly (e.g., portions of the reconstructed wavefront may require an increase or decrease in detector sensitivity of dynamic range). Step 122, transmitting a signal to the ALMD, through step 127, determining whether further wavefront reconstruction is required, are then repeated in a closed loop until a satisfactory wavefront reconstruction is obtained at which point the reconstructed wavefront is output at step 129.

Accordingly, because the number and position of the subfronts may be optimized in real time enabling different dissection patterns to be applied in parallel or in series, and because the fraction of the wavefront 100 sampled by ALMD 23 is greater than the fraction sampled by a conventional fixed lenslet array, and because reflective ALMDs are optically more efficient than conventional lenslets, a tremendous increase in speed, resolution and dynamic range is realized over conventional SHS devices that use fixed arrays.

In different embodiments, wavefront or wavefront portion 100 may be generated by passing a reference wavefront through an optical component of interest or by scattering a reference wavefront from a surface of interest. The reference wavefront may be plane wave or may be constructed in accordance with the anticipated optical properties or shape of the object or surface of interest.

In another embodiment, one or more ALMDs may be used to expand the wavefront to increase system dynamic range and avoid the overlap of individual sub fronts. Such expansion is particularly useful when dealing with very small area wavefronts, which must be magnified in order to acquire a sufficient number of data points. Wavefront expansion is also helpful for analyzing highly convergent wavefronts, where data acquisition is only available near the focal plane.

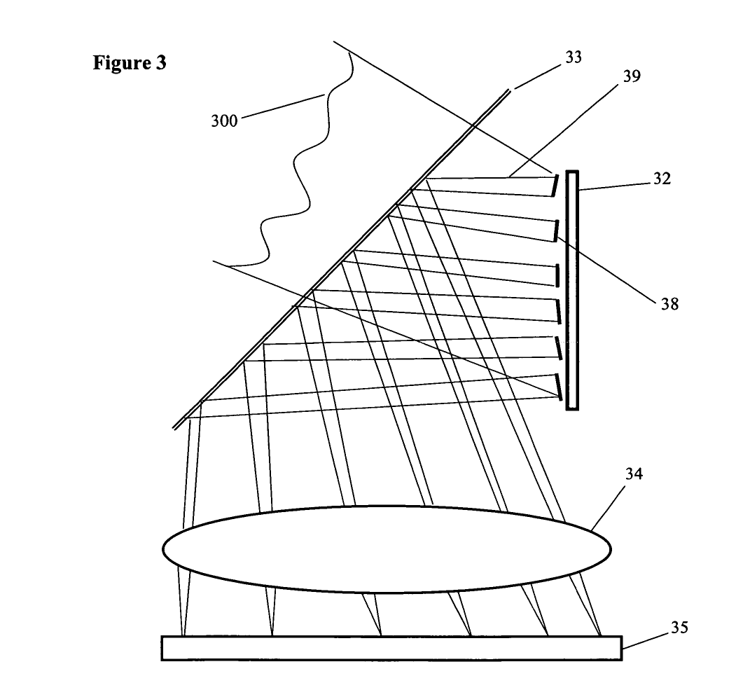

The schematic of FIG. 3 shows the use of an ALMD to expand a wavefront. Such wavefront expansion being desirable in applications such as opthamology where the diameter of the wavefront of interest may typically be only about 6 mm. As shown in FIG. 3, incident wavefront 300 is reflected off ALMD 32 using a plurality of two dimensional tilting mirrors 38, where each mirror may be individually computer-controlled to tilt to a predetermined angle, enabling sub fronts 39 to be expanded and placed in a controlled manner on projection lens 34 and focused on sensor 35. One or more partial or full reflectors/transmitters 33 may also be used to amplify or filter the expansion affected by ALMD 32. Alternatively, the quantity, location and size of elementary sub fronts 39 arriving at photosensor 35 may be optimized using a second computer-controlled ALMD in place of the reflector/transmitter 33. As in FIG. 2, computer-controlled closed loop feedback between ALMD 32 (and any ALMDs used in place of transmitter/reflector 33) and photosensor 35 may be used for real-time optimization of the size and placement of subfronts 39.

In another embodiment, an ALMD may be used to contract the wavefront to increase system dynamic range and avoid overlapping of the individual sub fronts. Such contraction being particularly useful for the very large in cross-section wavefront, where de-magnification is needed in order to acquire significant amount of data points. Wavefront contraction is helpful when analyzing highly diverging wavefronts, where data acquisition is only available from small fraction of the wavefront.

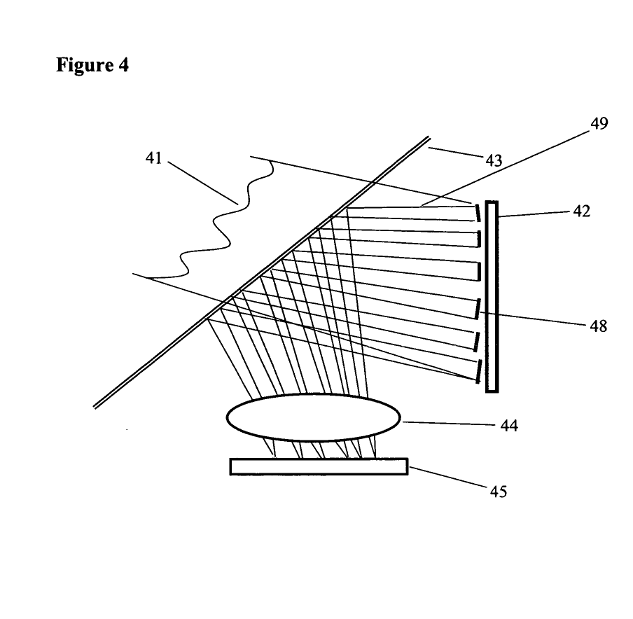

FIG. 4 shows the use of an ALMD to contract a wavefront. Incident wavefront 41 is reflected off ALMD 42 by a plurality of two dimensional tilting mirrors 48, where each mirror may be controlled individually and tilted at a predetermined angle to direct sub fronts 49 towards projection lens 44 that in turn focuses subfronts 49 onto sensor 45. As further shown in FIG. 4, partial or full additional reflectors/transmitters 43 may be used to amplify or filter the contraction effect. Alternatively, the quantity, location and size of elementary sub fronts 49 arriving at photosensor 45 may be optimized using a second computer-controlled ALMD in place of the of the reflector/transmitter 43. As in FIG. 2, computer-controlled closed loop feedback between ALMD 42 (and any ALMDs used in place of transmitter/reflector 43) and photosensor 45 may be used for real-time optimization of the size and placement of subfronts 49.

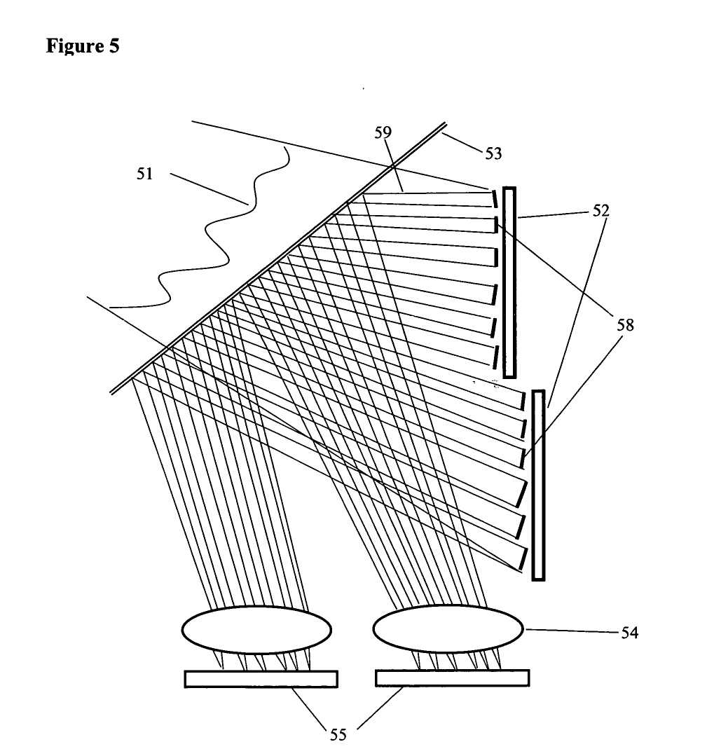

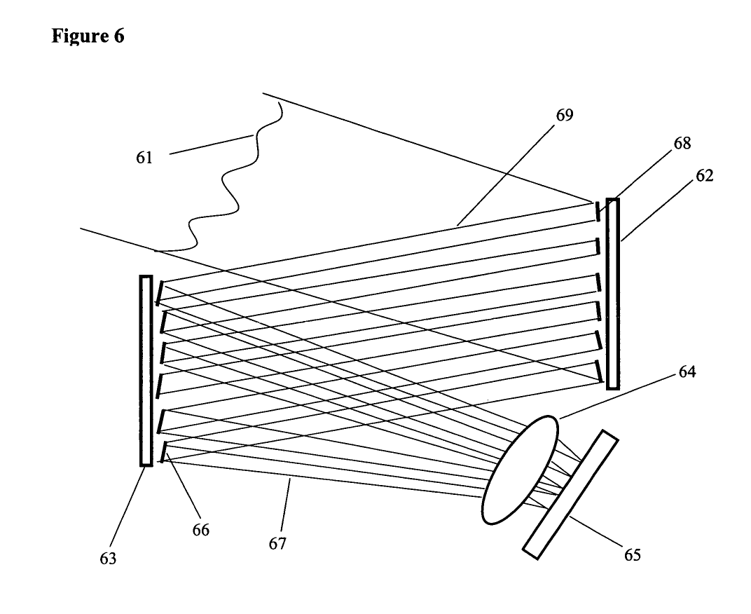

In yet another embodiment, a large wavefront may be processed with multiple ALMDs operating in parallel, as shown schematically in the FIG. 5. Large wavefront 51 is reflected off two parallel ALMDs 52, each having a plurality of two dimensional tilting mirrors 58, where each mirror may be controlled individually and tilted at predetermined angle, allowing sub fronts 59 to be directed onto projection lenses 54 and in turn focused onto sensors 55. As further shown in FIG. 5, partial or full additional reflectors transmitters 53 may be used to amplify or filter the expansion of the wavefront. Alternatively, the quantity, location and size of elementary sub fronts 59 arriving at photosensor 34 may be optimized using one or more ALMDs in addition to ALMDs 52, as explained below with reference to FIG. 6. As in FIG. 2, computer-controlled closed loop feedback between ALMD 52 (and any ALMDs used in place of transmitter/reflector 53) and photosensor 55 may be used for real-time optimization of the size and placement of subfronts 59.

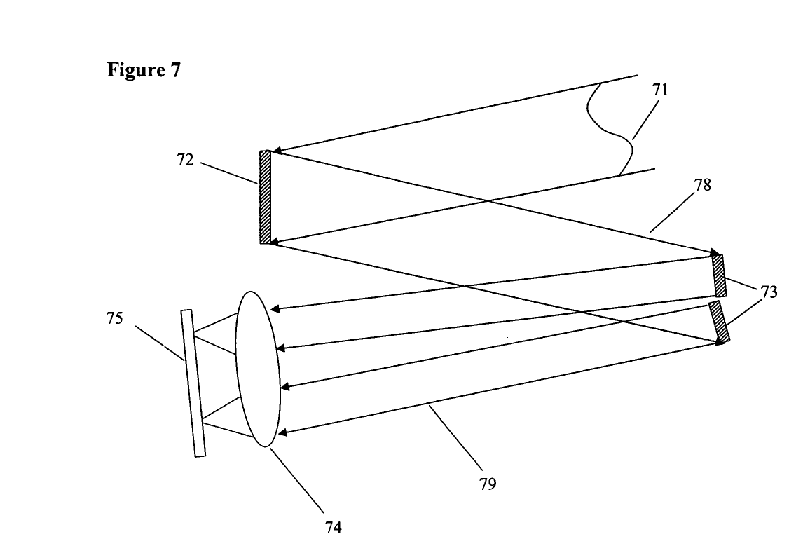

In another, embodiment, two ALMDs may be used in series for the further dissection and direction of subfronts. As shown in FIG. 6, wavefront 61 is first dissected using ALMD 62 into subfronts 68 and then directed onto second ALMD 63, which spreads sub-beams 67 even further apart. Correlation of the control of ALMD 62 and ALMD 63 allows for further filtering and secondary dissection of the sub-wavefront by employing different size mirrors or elements, 68 and 66, as shown and discussed with regard to FIG. 7. ALMD 63 may thus be used to further expand sub fronts 67 with respect to subfronts 69 as generated by the first element to dissect the wavefront, ALMD 62. A system of multiple sequential and non-sequential projection lenses 64 may also be used to direct the wavefront onto sensor element 65. Using sequential ALMDs and sequential projection lenses, desired subfront separation and sizes may be obtained.

The use of sequential ALMDs having different sized reflective elements is shown schematically in FIG. 7. Part of elementary wavefront 71 is first reflected by mirror element 72 of a first ALMD into subfronts 78 (only one of which is shown) and each subfront 78 is further dissected by reflection from multiple smaller mirror element 73 of a second ALMD to produce multiple subfronts 79. The subfronts 79 are then focused by a system of multiple sequential and non-sequential lenses 74 (only one of which is shown schematically) onto a photo-detector 75. Such two or more stage dissection of a wavefront may be used to produce large numbers of data points for the precise analysis of minor wavefront distortions.

In many instances, the wavefront distortion produced by an object may vary in a desired and specific manner, such as the distortions produced by cylindrical, toric or progressive focal lenses. Using a computer-controlled ALMD, dissection of the wavefront produced by such objects can be performed following a specific pattern to increase or decrease the spatial density of data points for specific regions. A predefined pattern or sequence of patterns may be used that varies data point density in a controlled manner across the regions of interest. This capability is particularly important when analyzing non-linear and complex optical elements. See, e.g., U.S. Pat. No. 5,825,476 to Abitol.

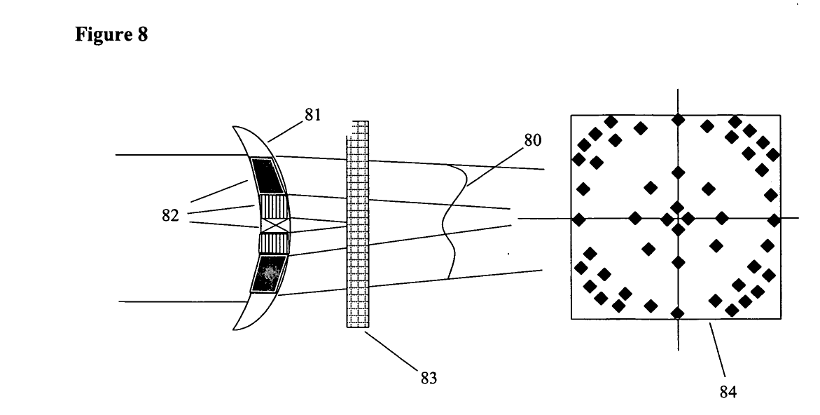

An example of such a defined pattern for analyzing a progressive power contact lens having three zones of different optical powers is shown in FIG. 8. Wavefront 80 is formed by a lens 81 having three zones 82 with different optical powers. The dissecting element 83—constituting a sensor with one or more computer-controlled ALMDs having refractive and/or reflective optical sub-elements for dividing wavefront 80 into subfronts—may be configured such that the spatial density of the data points sampled from the wavefront 80 varies across optical zones 82, as shown by pattern 84.

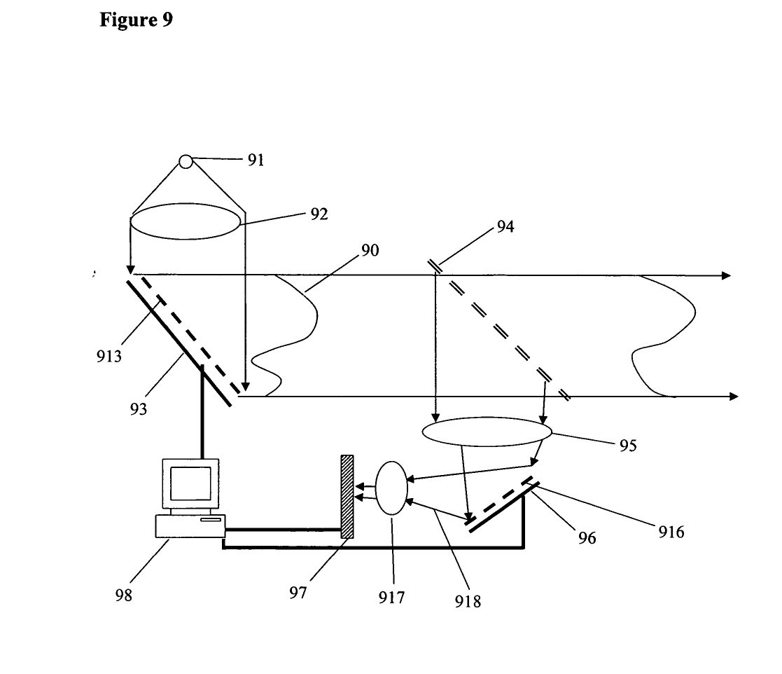

In another embodiment, active wavefront corrections may be performed using two or more ALMDs, where one or more ALMDs are used as wavefront dissecting devices and one or more ALMDs as wavefront forming (modulating) devices. As shown in FIG. 9, wavefront 90 is generated by light source 91 and processed by lens 92. After reflection off ALMD 93, having reflective elements 913, wavefront 90 propagates through a beam splitter 94 and a small fraction of wavefront 90 is directed onto ALMD 96 having reflective elements 916 via telescopic lens 95. Dissected subfronts 918 are then reflected onto light sensitive device 97 (a CCD, CMOS, PSD, etc.) through projection lens 917 and the resulting signal processed by personal computer 98. Personal computer 98, either directly or through a network, controls wavefront forming ALMD 93, enabling active correction to take place. In such a manner, a wavefront generator with closed loop feedback may be created.

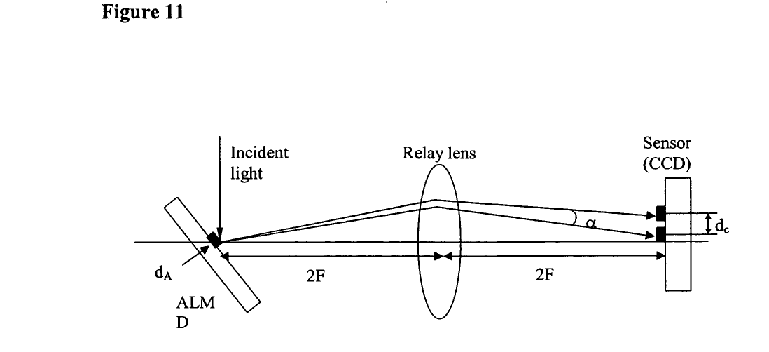

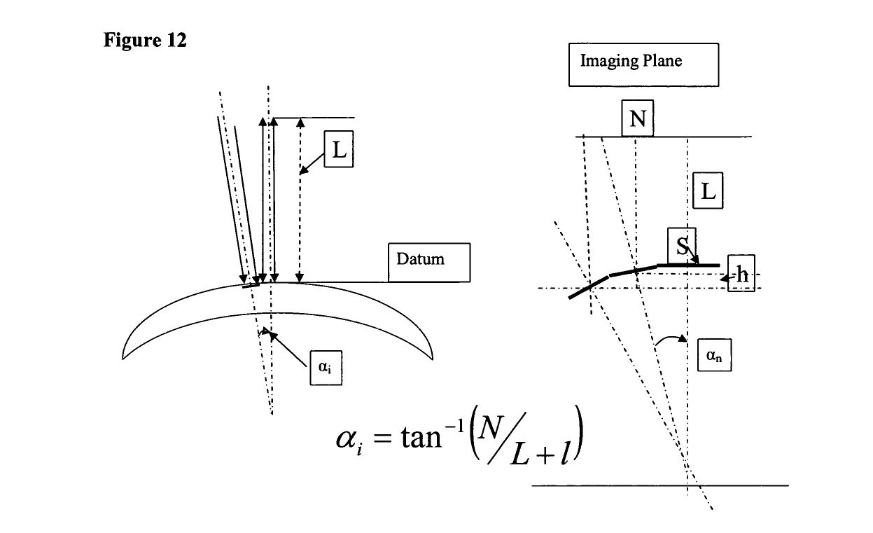

Without intending to be bound by any particular theory of operation, Appendix A, with reference to FIGS. 11 and 12, provides what is believed to be the theoretical performance parameters of the inventive method and system which shows significant improvement over conventional systems. A typical system implemented using commercially available components has a sensitivity of 0.53 nm and a dynamic range of 560 nm, with the possibility of sub-Angstrom sensitivity without significant sacrifice to dynamic range.

In another embodiment, the ALMD sensor may be used for three dimensional surface reconstruction by dissecting a wavefront reflected off a surface and then rebuilding the surface by elementary unit reconstruction. Surface reconstruction performed in such a manner being highly accurate and deterministic. The surface is illuminated by an incoming plane wave or by an incoming wave of a predetermined shape, i.e., carrying an image. Illuminating a surface with pre-imaged light can be particularly beneficial when surface is to be compared to a known dimension or profile.

An elementary wavefront is reflected from the elementary surface element Sᵢ with deflection in X, and Y axis which will determine location of the light streak on the imaging plane. Deflection angles, αᵢ, can be computed as shown in FIG. 11. Using the small angle approximation (that angles measured in radians are equal to their tangents) the elementary height difference “hᵢ” between datum plane and next elementary sector may be derived. The “h” elements located across i-amount of columns and k-amount of rows will fully characterize the surface with a spatial resolution, corresponding to the side length of unit equal to elementary wavefront section “S.” As set forth in Appendix A, the dimensions of a unit cube for reconstructing a surface may be as small as 15 μm.

In summary, the ALMD-based wave front sensor described herein with expanded range and dissection flexibility will be particularly useful in those fields where wave front analysis is already used. For example, in ophthalmics the inventive method and device may be used for analysis of the corneal surface of the human eye where system sensitivity can be set at different levels in different areas. The invention is particularly well-suited to the diagnosis and treatment of human eyesight because of its rapidity, flexibility, low energy losses and high flexibility compared to present systems. Other areas of application include astronomy, large optics, in the semiconductor industry and any optical task where very large or very small objects needed to be analyzed with high data fidelity and a large amount of data.

The foregoing discussion merely illustrates the principles of the invention. Various modifications and alterations to the described embodiments will be apparent to those skilled in the art in view of the teachings herein.

### APPENDIX A

The theoretical sensitivity and dynamic range of the device described in this invention can be evaluated with reference to FIG. 11. Let the minimum resolution of the imaging sensor be d_{c}; then, the minimum angle of a single ALMD element detectable by the sensor is

$$α = \frac{{d}_{c}}{4 F} ,$$

where F is the focal length of the relay lens. Given a resolution of the ALMD sensor of d_{A}, the smallest resolved optical path difference between adjacent elements of the wavefront is

$$δ = {d}_{A} \frac{{d}_{c}}{4 F} .$$

The dynamic range may be determined by assuming the maximum distance between the spots at the sensor is of the order of typical sensor size, i.e., d_{c}=Dₛₑₙₛₒᵣ˜15 μm.

Thus, taking commercially available systems, we have: d_{A} =14 μm, d_{c}=15 μm, F=100 mm. Thus, system sensitivity δ=0.53 nm. Further increase of the focal length of the lens and detection resolution can easily bring this number to a sub-angstrom level without sacrificing the dynamic range. For the layout above, the dynamic range of the system is ˜560 nm (˜2° wavefront slope error maximum).

The theoretically maximum dynamic range of 45 degrees (d_{A} =λ) makes 4F=Dₛₑₙₛₒᵣ. For a typical sensor with Dₛₑₙₛₒᵣ=15 mm, and dc=15 μm, the upper limit on sensitivity becomes then ˜28 nm.

The relay lens could be re-positioned to magnify the ALMD elements and provide for larger sensitivity. This increase will come, however, at the expense of reduction of the system dynamic range.

The reconstruction of surface topography, with reference to FIG. 12, may be understood according to the following relations:

$${α}_{i} = {tan}^{- 1} ( \frac{N}{L + l} )$$

$${h}_{ix} = {S}_{ix} tan {α}_{ix} = {S}_{ix} {α}_{ix}$$

$${h}_{iy} = {S}_{iy} tan {α}_{iy} = {S}_{iy} {α}_{iy}$$

$${h}_{i} = \frac{1}{2} ( {S}_{ix} {α}_{ix} + {S}_{iy} {α}_{iy} )$$

$${h}_{i}^{k} = {\sum }_{i = 0}^{k} {h}_{i} = \frac{1}{2} {\sum }_{i = 1}^{K} ( {S}_{ix} {α}_{ix} + {S}_{iy} {α}_{iy} )$$

We claim:

1. An apparatus for analyzing variance of an optical wavefront comprising:
an active light modulation device having a multiplicity of elements for dissecting a portion of the wavefront into a plurality of subfronts;
a detector for measuring the optical flux of a subset of the plurality of subfronts; and,
a central processing unit programmed to calculate the variance of the portion of the wavefront using optical flux measurements from the detector.

2. The apparatus of claim 1 wherein the multiplicity of elements of the active light modulation device comprises individually controllable mirrors.

3. The apparatus of claim 1 wherein the multiplicity of elements of the active light modulation device comprises windows or apertures having micro-mechanical shutters.

4. The apparatus of claim 1 wherein the multiplicity of elements of the active light modulation device comprise translucent windows having controllable transmissivities.

5. The apparatus of claim 1 wherein the active light modulation device is used to expand the portion of the wavefront.

6. The apparatus of claim 1 wherein the active light modulation device is used to contract the portion of the wavefront.

7. The apparatus in claim 1 wherein the detector comprises one or more CCD, CMOS, PSD or PIN type detectors.

8. The apparatus of claim 1 wherein the multiplicity of elements is disposed in a pre-determined image dissection pattern.

9. The apparatus of claim 1 wherein the multiplicity of elements is disposed in an image dissection pattern that is generated by modifying a pre-determined image dissection pattern in accordance with the calculated variance of the portion of the wavefront.

10. The apparatus of claim 1 wherein the optical wavefront is generated by passing a reference wavefront through an optical component.

11. The apparatus of claim 1 wherein the optical wavefront is generated by scattering a reference wavefront from a surface.

12. The apparatus of claim 1 further comprising optics for directing at least a portion of the optical wavefront onto the active light modulation device.

13. A method for analyzing variance of an optical wavefront comprising the steps of:
dissecting at least a portion of the wavefront into a plurality of subfronts using an active light modulation device having a multiplicity of elements;
measuring the optical flux of a subset of the plurality of subfronts using a detector; and,
calculating the variance of the portion of the wavefront using the optical flux measurements from the detector.

14. The method of claim 13 wherein the multiplicity of elements of the active light modulation device comprises individually controllable mirrors.

15. The method of claim 13 wherein the multiplicity of elements of the active light modulation device comprises windows or apertures having micro-mechanical shutters.

16. The method of claim 13 wherein the multiplicity of elements of the active light modulation device comprises translucent windows having controllable transmissivities.

17. The method of claim 13 further comprising the step of using the active light modulation device to expand the portion of the wavefront.

18. The method of claim 13 further comprising the step of using the active light modulation device to contract the portion of the wavefront.

19. The method of claim 13 wherein the detector comprises one or more CCD, CMOS, PSD or PIN type detectors.

20. The method of claim 13 further comprising the step of disposing the multiplicity of elements in a pre-determined image dissection pattern.

21. The method of claim 13 further comprising the step of disposing the multiplicity of elements in an image dissection pattern that is generated by modifying a pre-determined image dissection pattern in accordance with the calculated variance.

22. The method of claim 13 further comprising the step of generating the optical wavefront by passing a reference wavefront through an optical component.

23. The method of claim 13 further comprising the step of generating the optical wavefront by scattering a reference wavefront from a surface.

24. The method of claim 13 further comprising the step of using optics to direct at least a portion of the optical wavefront onto the active light modulation device.

25. A method for analyzing variance of an optical wavefront comprising the steps of:
dissecting at least a portion of the wavefront into a plurality of subfronts using a first active light modulation device having a multiplicity of elements;
expanding at least one subset of the plurality of subfronts using a second active light modulation device having a second multiplicity of elements;
measuring the optical flux of at least a subset of the expanded subfronts using a detector; and,
calculating the variance of the portion of the wavefront using optical flux measurements from the detector.

26. The method of claim 25 wherein the multiplicity of elements of at least one of the first or second active light modulation device comprises individually controllable mirrors.

27. The method of claim 25 wherein the multiplicity of elements of at least one of the first or second active light modulation device comprises windows or apertures having micro-mechanical shutters.

28. The method of claim 25 wherein the multiplicity of elements of at least one of the first or second active light modulation device comprises translucent windows having controllable transmissivities.

29. The method of claim 25 wherein the detector comprises one or more CCD, CMOS, PSD or PIN type detectors.

30. The method of claim 25 further comprising the step of disposing at least one of the multiplicity of elements of the first or second active light modulation device in a pre-determined image dissection pattern.

31. The method of 25 further comprising the step of disposing at least one of the multiplicity of elements of the first or second active light modulation device in an image dissection pattern that is generated by modifying a pre-determined image dissection pattern in accordance with the calculated variance.

32. The method of claim 25 further comprising the step of generating the optical wavefront by passing a reference wavefront through an optical component.

33. The method of claim 25 further comprising the step of generating the optical wavefront by scattering a reference wavefront from a surface.

34. The method of claim 25 further comprising the step of using optics to direct at least a portion of the optical wavefront onto the first active light modulation device.
